(19) United States
(12) Patent Application Publication
(10) Pub. No.: US 2013/0147028 A1
(43) Pub. Date: Jun. 13, 2013

(54) HEAT SPREADER FOR MULTIPLE CHIP SYSTEMS

(71) Applicants: Michael Z. Su, Round Rock, TX (US); Bryan Black, Spicewood, TX (US); Gamal Refai-Ahmed, Markham (CA)

(72) Inventors: Michael Z. Su, Round Rock, TX (US); Bryan Black, Spicewood, TX (US); Gamal Refai-Ahmed, Markham (CA)

(21) Appl. No.: 13/313,584

(22) Filed: Dec. 7, 2011

(51) Int. Cl. H01L 23/34; H01L 21/50

(52) U.S. Cl. 257/712; 438/122; 257/E21.499; 257/E23.08

(57) ABSTRACT

Various heat spreaders and methods of making and using the same are disclosed. In one aspect, a method of manufacturing is provided that includes forming a heat spreader that has a surface adapted to establish thermal contact with a first semiconductor chip and a second semiconductor chip on a substrate. The surface includes a first portion adapted to thermally contact a solder-based thermal interface material and a second portion having an opening adapted to hold an organic thermal interface material.

### BACKGROUND OF THE INVENTION

1. Field of the Invention

This invention relates generally to semiconductor processing, and more particularly to semiconductor chip packaging and to methods of making the same.

2. Description of the Related Art

One form of conventional packaged semiconductor chip devices has involved the mounting of a single semiconductor chip on a package substrate composed of a ceramic or laminate or organic materials, such as epoxy resins. More recently, designers have begun to turn to multi-chip systems in which one or more semiconductor chips are positioned on a single package substrate. In some of these systems, one or more of the semiconductor chips may be high powered devices, such as microprocessors, and others may be relatively lower powered devices, such as memory devices. Thermal management of systems involving a hybrid of high power and low power semiconductor chips may still require thermal management through the use of a heat spreader in thermal contact with the semiconductor chips by way of thermal interface material layers. The usage of a solder-based thermal interface material has certain advantages for high powered devices due to the ability of solder to withstand higher temperatures and the greater thermal conductivity thereof. Organic thermal interface materials can sometimes yield the requisite thermal properties to transfer heat away from high power dissipating devices. However, under certain circumstances, organic thermal interface materials may not be sufficiently thermally conductive. Solder-based thermal interface materials may be problematic for usage with stacked semiconductor chips since it is sometimes difficult to prevent the solder from cascading down the sides of the stack of semiconductor chips and potentially invading the conductor structures in between such chips.

The present invention is directed to overcoming or reducing the effects of one or more of the foregoing disadvantages.

### SUMMARY OF EMBODIMENTS OF THE INVENTION

In accordance with one aspect of an embodiment of the present invention, a method of manufacturing is provided that includes forming a heat spreader that has a surface adapted to establish thermal contact with a first semiconductor chip and a second semiconductor chip on a substrate. The surface includes a first portion adapted to thermally contact a solder-based thermal interface material and a second portion having an opening adapted to hold an organic thermal interface material.

In accordance with another aspect of an embodiment of the present invention, a method of conveying heat from a first semiconductor chip and a second semiconductor chip on a substrate is provided. The method includes placing a solder-based thermal interface material in thermal contact with the first semiconductor chip and an organic thermal interface in thermal contact with the second semiconductor chip. A surface of a heat spreader is placed in thermal contact with the first semiconductor chip and the second semiconductor chip. The surface includes a first portion thermally contacting the solder-based thermal interface material and a second portion having an opening to hold at least a portion of the organic thermal interface material.

In accordance with another aspect of an embodiment of the present invention, an apparatus for conveying heat from a first semiconductor chip and a second semiconductor chip on a substrate is provided. The apparatus includes a heat spreader that has a surface adapted to establish thermal contact with the first semiconductor chip and the second semiconductor chip. The surface includes a first portion adapted to thermally contact a solder-based thermal interface material and a second portion having an opening adapted to hold an organic thermal interface material.

In accordance with another aspect of an embodiment of the present invention, an apparatus is provided that includes a substrate and a first semiconductor chip and a second semiconductor chip mounted in spaced apart relation on the substrate. A heat spreader is provided that has a surface adapted to establish thermal contact with the first semiconductor chip and the second semiconductor chip. The surface includes a first portion adapted to thermally contact a solder-based thermal interface material and a second portion having an opening adapted to hold an organic thermal interface material. A solder-based thermal interface material is in thermal contact with the first portion and the first semiconductor chip and an organic thermal interface material is positioned at least partially in the opening and in thermal contact with the second portion and the second semiconductor chip.

### BRIEF DESCRIPTION OF THE DRAWINGS

The foregoing and other advantages of the invention will become apparent upon reading the following detailed description and upon reference to the drawings in which:

FIG. 1 is a partially exploded pictorial view of an exemplary embodiment of a semiconductor chip device that includes a substrate upon which multiple semiconductor chips are mounted and a lid;

FIG. 2 is a pictorial view of the exemplary lid of FIG. 1 flipped over;

FIG. 3 is a pictorial view of an alternate exemplary organic thermal interface material;

FIG. 4 is a pictorial view like FIG. 2, but of an alternate exemplary lid; and

FIG. 5 is a pictorial view like FIG. 1, but depicting assembly of the lid and the substrate.

### DETAILED DESCRIPTION OF SPECIFIC EMBODIMENTS

Various heat spreaders useful with, for example, stacked semiconductor chips on a substrate are disclosed. In one aspect, a heat spreader functional as a lid is mounted in thermal contact with two semiconductor chips spaced apart on the substrate. The heat spreader has a surface that includes a first portion adapted to thermally contact a solder-based thermal interface material and a second portion that has an opening adapted to hold an organic thermal interface material. Additional details will now be described.

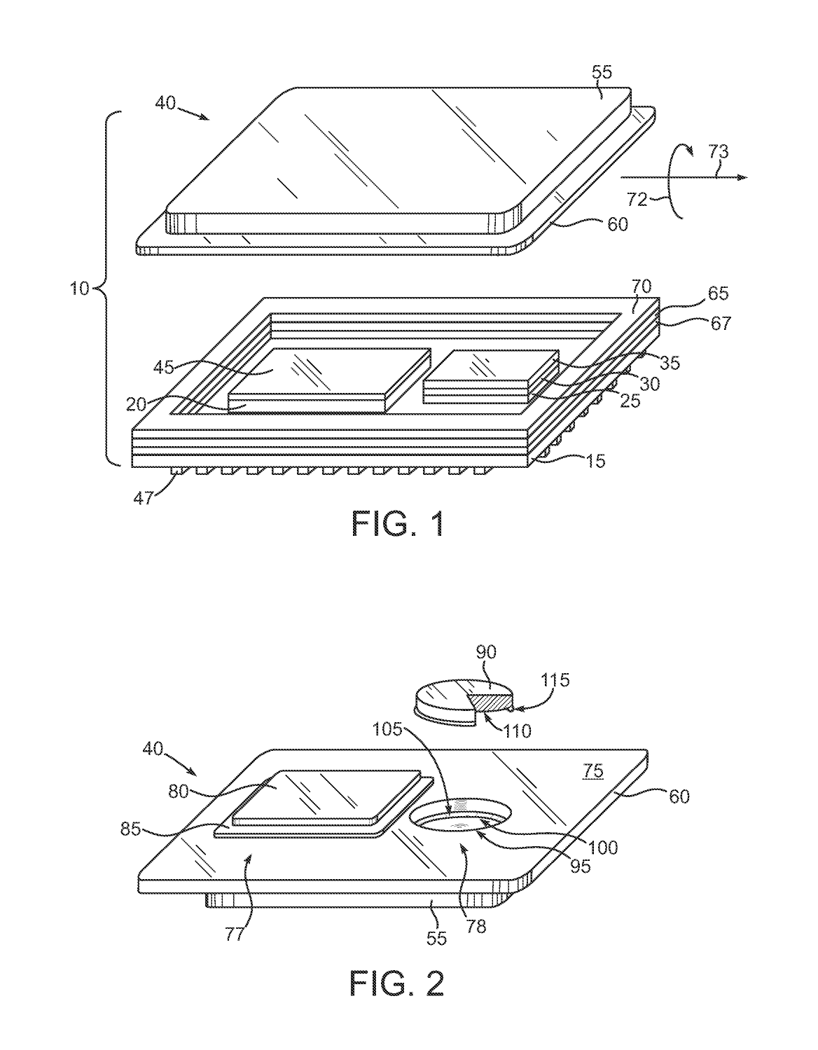

In the drawings described below, reference numerals are generally repeated where identical elements appear in more than one figure. Turning now to the drawings, and in particular to FIG. 1, therein is shown a partially exploded pictorial view of an exemplary embodiment of a semiconductor chip device 10 that includes a substrate 15 upon which a semiconductor chip 20 and a stack of semiconductor chips 25, 30 and 35 are mounted. The semiconductor chip 20 may stand alone as depicted or be included in a stack of additional semiconductor chips (not visible) much like the stack of semiconductor chips 25, 30 and 35. The number of semiconductor chips like the semiconductor chips 25, 30 and 35 may be one or more as desired. The semiconductor chips 25, 30 and 35 may be interconnected electrically by through-silicon vias and microbumps or other interconnect structures (not shown). The semiconductor chip device 10 includes a heat spreader or lid 40 that may be mounted on the circuit board 15 to convey heat from the semiconductor chips 20, 25, 30 and 35.

Functionally speaking, the semiconductor chips 20, 25, 30 and 35 may be any of a large number of different types of circuit devices used in electronics, such as, for example, microprocessors, graphics processors, combined microprocessor/graphics processors, application specific integrated circuits, interposers, memory devices or the like, and may be single or multi-core or even stacked with or accompanied by additional dice. The semiconductor chips 20, 25, 30 and 35 may be constructed of bulk semiconductor, such as silicon or germanium, or semiconductor-on-insulator materials, such as silicon-on-insulator materials. Even insulating materials are contemplated. The semiconductor chip 20 is provided with a backside metallization structure 45 that facilitates metallurgical bonding with a solder-based thermal interface material (not visible in FIG. 1) used to establish a thermally conductive pathway to the heat spreader 40. The composition of the backside metallization structure 45 will depend on the composition of the solder-based thermal interface material. One example suitable for an indium-based thermal interface material includes, proceeding from top down, a gold film, a nickel-vanadium film, a titanium film and finally an aluminum film. The semiconductor chip 35 is also fitted with a thermal interface material that is not visible in FIG. 1 but will be shown in subsequent figures. However, since the semiconductor chips 25, 30 and 35 dissipate less power, an organic thermal interface material may be used on the semiconductor chip 35 as described more fully below.

The substrate 15 may be a semiconductor chip package substrate, a semiconductor interposer, a circuit card, a pinned socket adapter, or virtually any other type of printed circuit board. Although a monolithic structure could be used for the substrate 15, a more typical configuration will utilize a build-up design. In this regard, the substrate 15 may consist of a central core upon which one or more build-up layers are formed and below which an additional one or more build-up layers are formed. The core itself may consist of a stack of one or more layers. If implemented as a semiconductor chip package substrate, the number of layers in the substrate 15 can vary from four to sixteen or more, although less than four may be used. So-called “coreless” designs may be used as well. The layers of the substrate 15 may consist of an insulating material, such as various well-known epoxies, interspersed with metal interconnects. A multi-layer configuration other than buildup could be used. Optionally, the substrate 15 may be composed of well-known ceramics or other materials suitable for package substrates or other printed circuit boards. The substrate 15 may be provided with a number of conductor traces and vias and other structures (not visible) in order to provide power, ground and signals transfers between the semiconductor chips 20, 25, 30 and 35 and another device (not shown). In this illustrative embodiment, the substrate 15 is configured as a semiconductor chip package substrate. To interface electrically with other devices, such as a system board or electronic device (not shown), the substrate 15 may be provided with an interconnect structure such as the depicted land grid array 45. However, the skilled artisan will appreciate that other interconnect schemes, such as pin grid arrays, ball grid arrays, or other interconnect schemes may be used as desired.

The semiconductor chip device 10 includes a heat spreader 40 that functions as a heat spreader. In this illustrative embodiment, the heat spreader 40 is a top hat design. However, the skilled artisan will appreciate that bathtub designs, pure block designs or other configurations may be used as well. Indeed, the heat spreader 40 may take on virtually a limitless number of configurations and be composed of a variety of thermally conductive materials such as well-known ceramics or metallic materials as desired. Some exemplary materials include copper, nickel jacketed copper, anodized aluminum, aluminum-silicon-carbon, aluminum nitride, boron nitride or the like. In this illustrative embodiment where a top hat design is utilized, the heat spreader 40 includes a top portion 55 that is circumscribed laterally by a flange 60. The top portion 55 and the flange 60 may be integrally formed or joined by adhesives, metallurgical processes or fasteners.

The heat spreader 40 may be designed to seat on a stiffener frame 65 that is secured to the substrate 15. The stiffener frame 65 may be composed of a variety of materials, such as epoxies, plastics or even metals, such as copper, aluminum, stainless steel or the like. The stiffener frame 65 may be secured to the substrate 15 by an adhesive 67. The adhesive 67 may be a variety of materials, such as epoxies or a silicone-based thixotropic adhesive. Optionally, a metallic bond using lead-free or lead-based solder may be used if the frame 65 can withstand the melting temperature of the solder. The heat spreader 40 and in particular the flange 60 is secured to the stiffener frame 65 by way of an adhesive 70, which may be composed of the same materials as the adhesive 67.

Additional details of the heat spreader 40 may be understood by referring now also to FIG. 2, which is a pictorial view of the heat spreader 40 rotated in the direction of the arrow 72 around the axis 73 in FIG. 1 to an inverted position. Thus, the positions of the top portion 55 and the bill 60 of the heat spreader 40 are reversed in FIG. 2. An underside 75 of the heat spreader 40 includes a portion 77 slated to make thermal contact with the semiconductor chip 20 and another portion 78 slated to make thermal contact with the semiconductor chip 35. The surface 75 may be a relatively planar surface as depicted in FIG. 2 with a few notable exceptions. Note that a solder-based thermal interface material 80 may be positioned on a solder wetting layer 85 applied to the surface 75. It is possible to place the solder-based thermal interface material 80 as a preform on either the solder wetting layer 80 or the semiconductor chip 20 or both. The solder-based thermal interface material 80 may be composed of a variety of different types of solder such as indium alone or mixed with another metal, well-known lead-based solders such as eutectics, well-known lead-free solders, such as tin-silver-copper or other solders. The composition of the solder wetting layer 85 may be selected from a variety of materials that are suitable to wet the particular composition of the solder-based thermal interface material 80. Examples include gold, platinum, palladium or the like. In this illustrative embodiment where indium is used as the solder-based thermal interface material 80 the solder wetting layer 85 may be composed of gold. The solder wetting layer 85 composed of gold may be applied to the surface 75 of the heat spreader 40 by, for example, well-known plating processes. The solder-based thermal interface material 80 is designed to metallurgically bond to the backside metallization 45 of the semiconductor chip 20 shown in FIG. 1 during a post lid mounting reflow process.

To establish thermal contact between the heat spreader 40 and the semiconductor chip 35 shown in FIG. 1, an organic thermal interface material 90 (shown partially cut away) may be positioned in an opening 95 in the heat spreader 40. The organic thermal interface material 90 is advantageously composed of polymeric materials such as, for example, silicone rubber mixed with aluminum particles and zinc oxide. Optionally, compliant base materials other than silicone rubber and thermally conductive particles other than aluminum may be used.

The organic thermal interface material 90 is shown exploded from the opening 95. Here, the opening 95 and thus the thermal interface material 90 normally disposed therein may have circular footprints. However, the skilled artisan will appreciate that other shapes may be used for the opening and the thermal interface material 90 as desired. To inhibit the movement of the thermal interface material 90 out of the opening 95, the various contours may be applied to the opening 95. In this regard, the bottom 100 of the opening 95 may be dished to form a concave surface that terminates peripherally in a recessed trench 105. The combination of the concave bottom 100 and the trench 105 produces a convex lower surface 110 of the thermal interface material 90 as well as a peripherally positioned bead 115 that enhances adhesion between the thermal interface material 90 and the opening 95.

The thicknesses of the thermal interface materials 80 and 90 contacting the semiconductor chips 20 and 35, respectively, is termed the bond line thickness. Better thermal conductivity is achieved where the bond line thickness is maintained within some range during thermal cycling. The adhesive 70 acts like a spring to help keep the bond line thickness fairly uniform.

The opening 95 may be formed in the surface 75 of the heat spreader 40 in a variety of ways. Examples include machining, forging, casting or the like. If, as in this illustrative embodiment, the heat spreader 40 is a clad structure in which a copper core is surrounded by a nickel jacket then the exposed surfaces of the opening 95 may be nickel plated as well.

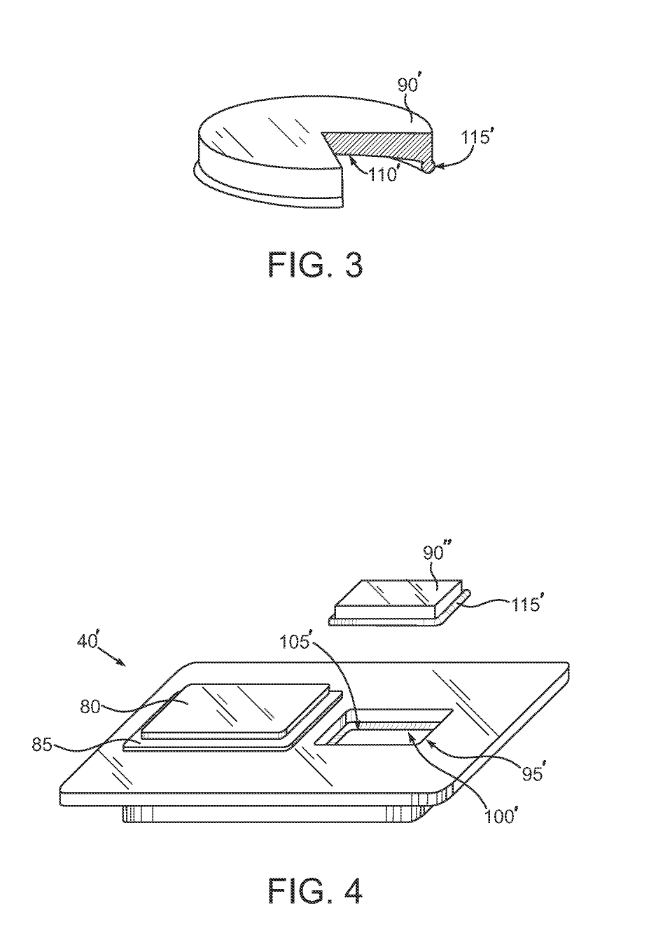

In the illustrative embodiment depicted in FIG. 2, the opening 95 includes a concave bottom 100 that produces a convex lower surface 110 in the thermal interface material 90. However, the skilled artisan will appreciate that other profiles are possible. In this regard, attention is now turned to FIG. 3, which is a pictorial view of an alternate exemplary thermal interface material 90′ that may be positioned in an opening like the opening 95 but with the opening 95 including a convex as opposed to a concave bottom. Thus, when positioned in such a convex opening, the thermal interface material 90′ (shown partially cut away) will have a lower concave profile 110′ in addition to the peripherally disposed bead 115.

As noted above, an opening to accommodate an organic thermal interface material may take on other than a circular footprint. In this regard, attention is now turned to FIG. 4, which is a pictorial view like FIG. 2 but of an alternate exemplary heat spreader 40′ that includes a solder-based thermal interface material 80 and a solder wetting layer 85 as generally described above. In this illustrative embodiment however, an opening 95′ is provided with a rectangular footprint which may be rectangular or square as desired. The opening 95 may further include a dished bottom 100′ that terminates peripherally with a recessed trench 105′ that function like the concave bottom 100 and trench 105 described above, albeit in the context of a rectangular footprint. Note that the organic thermal interface material 90″ with a corresponding rectangular footprint and rectangular peripheral bead 115′ is shown exploded from the opening 95′. The same types of materials may be used for the organic thermal interface material 90″.

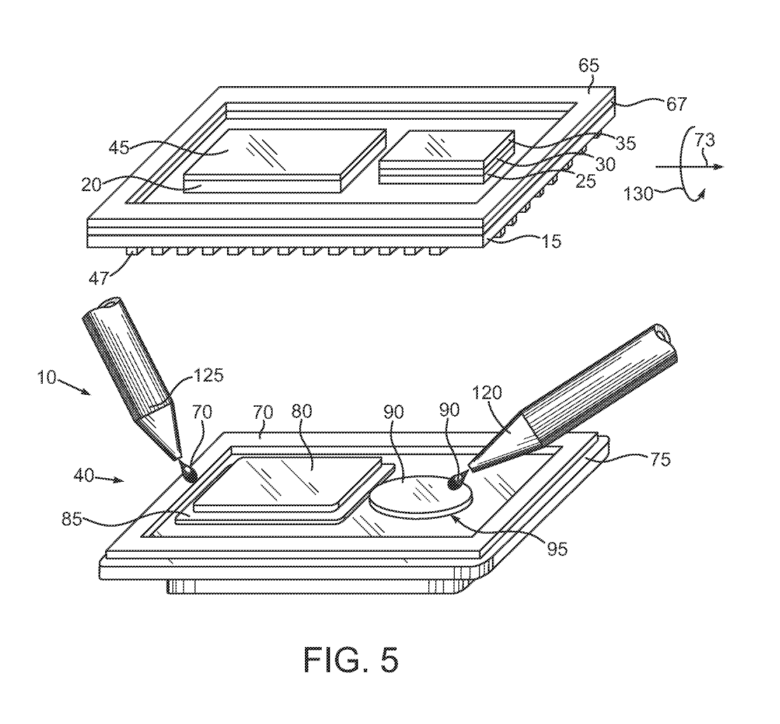

An exemplary method for assembling the semiconductor chip device 10 may be understood by referring now to FIG. 5, which is a partially exploded pictorial view depicting the substrate 15 with the semiconductor chips 20, 25, 30 and 35, the stiffener frame 65 and adhesive 67 already positioned thereon. At this point, the heat spreader 40 may be rotated to the upside down position as shown in FIG. 5 and the solder-based thermal interface material 80 may be positioned on the solder wettable layer 85 as shown. A suitable applicator 120 may be used to dispense the organic thermal interface material 90 in the opening 95. A technical goal of fashioning the opening 95 as illustrated in FIG. 2 is to restrain the lateral movement of the organic thermal interface material 90 toward the solder thermal interface material 85 which might otherwise interfere with metallurgical bonding with the backside metallization 45 of the semiconductor chip 20. The adhesive 70 may be applied to the surface 75 of the heat spreader 40 as a bead is shown by way of a suitable applicator 125. By applying the organic thermal interface material 90 with the heat spreader 40 in the upside down position as shown in FIG. 5, gravity may assist in both the dispersal of thermal interface material 90 in the opening 95 but the restraint of lateral movement thereof. At this point, the substrate 15 may be rotated about the axis 73 as suggested by the arrow 130 and the stiffener frame 65 seated on the adhesive bead 70. The adhesive 70 may be pressure activated, heat activated or by some other stimulus. A solder reflow may be performed at this point to establish a metallurgical bonding between the solder-based thermal interface material 80 and the backside metallization 45 of the semiconductor chip 20. For example, where indium is the solder-based thermal interface material 80, a heating process may be performed to elevate the solder-based thermal interface material 80 above 157° C. for about 20 to 30 seconds. A cool down will follow the reflow. A suitable flux application (not shown) may precede solder application and reflow.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
forming a heat spreader having a surface adapted to establish thermal contact with a first semiconductor chip and a second semiconductor chip on a substrate, the surface including a first portion adapted to thermally contact a solder-based thermal interface material and a second portion having an opening adapted to hold an organic thermal interface material.

2. The method of claim 1, comprising forming the opening with a contoured bottom.

3. The apparatus of claim 2, wherein the contoured bottom comprises a peripheral trench.

4. The method of claim 1, wherein the heat spreader comprises a top portion and a flange portion.

5. The method of claim 1, comprising mounting the heat spreader on the substrate and in thermally contacting the first semiconductor chip with the solder-based thermal interface material and the second semiconductor chip with the organic thermal interface material, a portion of the organic thermal interface material being held by the opening.

6. The method of claim 5, wherein the mounting comprises coupling a stiffener frame to the substrate and coupling the heat spreader to the stiffener frame.

7. The method of claim 1, comprising applying a solder wetting layer on the first portion.

8. The method of claim 1, comprises filling the opening with the organic thermal interface material and mounting the substrate on the surface.

9. A method of conveying heat from a first semiconductor chip and a second semiconductor chip on a substrate, comprising:
placing a solder-based thermal interface material in thermal contact with the first semiconductor chip and an organic thermal interface in thermal contact with the second semiconductor chip; and
placing a surface of a heat spreader in thermal contact with the first semiconductor chip and the second semiconductor chip, the surface including a first portion thermally contacting the solder-based thermal interface material and a second portion having an opening to hold at least a portion of the organic thermal interface material.

10. The method of claim 9, wherein the substrate includes at least one other semiconductor chip positioned beneath the second semiconductor chip.

11. The method of claim 9, wherein the substrate comprises a package substrate.

12. An apparatus for conveying heat from a first semiconductor chip and a second semiconductor chip on a substrate, comprising:
a heat spreader having a surface adapted to establish thermal contact with the first semiconductor chip and the second semiconductor chip, the surface including a first portion adapted to thermally contact a solder-based thermal interface material and a second portion having an opening adapted to hold an organic thermal interface material.

13. The apparatus of claim 12, wherein the opening comprises a contoured bottom.

14. The apparatus of claim 13, wherein the contoured bottom comprises a peripheral trench.

15. The apparatus of claim 12, wherein the heat spreader comprises a top portion and a flange portion.

16. The apparatus of claim 12, comprising a solder-based thermal interface material coupled to the first portion and an organic thermal interface material positioned at least partially in the opening.

17. An apparatus, comprising:
a substrate;
a first semiconductor chip and a second semiconductor chip mounted in spaced apart relation on the substrate;
a heat spreader having a surface adapted to establish thermal contact with the first semiconductor chip and the second semiconductor chip, the surface including a first portion adapted to thermally contact a solder-based thermal interface material and a second portion having an opening adapted to hold an organic thermal interface material; and
a solder-based thermal interface material in thermal contact with the first portion and the first semiconductor chip and an organic thermal interface material positioned at least partially in the opening and in thermal contact with the second portion and the second semiconductor chip.

18. The apparatus of claim 17, wherein the opening comprises a contoured bottom.

19. The apparatus of claim 18, wherein the contoured bottom comprises a peripheral trench.

20. The apparatus of claim 17, wherein the heat spreader comprises a top portion and a flange portion.

21. The apparatus of claim 17, comprising at least one other semiconductor chip positioned beneath the second semiconductor chip.

22. The apparatus of claim 17, wherein the substrate comprises a package substrate.

23. The apparatus of claim 17, comprising a stiffener frame coupled to the substrate, the heat spreader being coupled to the stiffener frame.
